(19) United States
(12) Patent Application Publication
(10) Pub. No.: US 2008/0191707 A1
(43) Pub. Date: Aug. 14, 2008

(54) Configurable interface device

(75) Inventors: Kenneth M. Collins, Weare, NH (US); Allen Baldvins, Merrimack, NH (US)

Correspondence Address: BOURQUE & ASSOCIATES;INTELLECTUAL PROPERTY ATTORNEYS, P.A., 835 HANOVER STREET, SUITE 301, MANCHESTER, NH, 03104, US

(73) Assignee: ARC Radar and Communication Services, LLC

(21) Appl. No.: 10/973,082

(22) Filed: Oct. 25, 2004

Related U.S. Application Data
(60) Provisional application No. 60/514,761, filed on Oct. 27, 2003.

(51) Int. Cl. G01R 31/02

(52) U.S. Cl. 324/537

(57) ABSTRACT

The configurable interface device (CID) is a modular, high-density, high-performance electronic test interface that includes a circuit card assembly and mechanical interface. The mechanical interface provides proper alignment to an interface test adapter (ITA), and electrical engagement, or disengagement. The circuit card assembly routes external high-speed electrical stimulus and response signals to sockets where configurable interconnections re-route these signals to an interface test adapter, and are carried through to the device under test (DUT).

### CROSS-REFERENCE TO RELATED APPLICATIONS

This application is related to U.S. Patent Application No. 60/514,761 filed Oct. 27, 2003 entitled Configurable Interface Device, which is incorporated fully herein by reference.

### TECHNICAL FIELD

The present invention relates generally to electrical test and measurement field and more specifically, to the electro-mechanical interface of electrical test equipment to electrical devices under test.

### BACKGROUND INFORMATION

The ultimate goal of a test interface is to connect test equipment to a device under test with the best possible signal integrity. Cost, durability, maintainability, ease of use, physical size and safety are all constraints for practical application of test interfaces.

A traditional test interface utilizes a test receiver and an Interface Test Adapter (ITA). The receiver is an array of mechanically aligned test signal connectors designed to mate with a matching/removable Interface Test Adapter (ITA). Test equipment signals are connected to the equipment side of the receiver. ITAs are connected to the device side of the receiver. The ITA routes and/or conditions test signals from the device under test to the receiver interface and to and from the test equipment.

Receivers of this type use mechanical aids such as levers and cams and heavy mechanical frames to support the array of simultaneous connections. They generally support one device under test per ITA due to the specialized electronic test signal routing and conditioning required for each device under test. Thus, one ITA must be designed and manufactured for each device to be tested.

### SUMMARY

Accordingly, it is an object of the present invention is to provide electrical connections between externally generated stimulus signals (typically from a piece of test equipment) and/or received response signals (from a device under test), to a device under test with high signal integrity through minimized electrical trace length and controlled trace impedance.

Yet another object of the invention is to provide a universally re-configurable signal array such that a test interface configuration may be used for numerous devices under test, utilizing a single interface test adapter thereby minimizing recurring costs for testing future devices under test requiring the same type of test adapter.

A further object of the invention is to provide safety features to protect devices under test from incorrect power and signal connection.

A still further object of the invention is to minimize recurring time and labor for interface test adapter development over current methods and to reduce size, weight, and recurring cost of interface test adapters.

An additional object of the invention is the electrical identification of signals used to ensure

proper signal routing to a validated device under test, which thereby protects incorrect devices from having power applied.

Yet another object of the invention is to provide a universal quick connect and disconnect of an interface test adapter, which assures easy mechanical alignment and solid electrical connection between the configurable interface device and device under test.

According to one embodiment of the present invention, the invention provides electrical signal routing, or mapping, which is accomplished in the following manner:

Commercial-off-the-shelf (COTS) test equipment is interfaced to a configurable interface device (CID) through one or more Equipment Interface Connectors (EIC). The CID contains one or more equipment interface connector groups. Each equipment interface connector group consists of one or more columns, each comprised of one 25×2 (50) pin header connectors. The electrical signals from the equipment interface connectors are routed to a user configurable signal connection array. In the preferred embodiment, the user configurable signal connection array includes four 21×21 (441) configurable grid array (CGA) sockets. These four CGAs may also be interconnected to one or more user grid arrays (UGAs). Zero insertion force (ZIF) adapters are mounted and electrically connected to the CGAs and UGAs. The ZIF sockets accept low-cost, high-density, wire wrappable connectors called CGA adapters that are then used to map test equipment signals back into the configurable interface device and then over to the device under test grid array (UGA), through the interface test adapter and ultimately to the device under test. Pin grid arrays may be either stand-alone or mounted to the interface test adapters (ITA).

The interface test adapter makes direct electrical connections with either the CGAs or UGAs. A mechanical swing arm/cam device electrically engages, or disengages, the ZIFs sockets to the interface test adapter. Application specific cross-connections are made externally at each CGA and passed through to the UGAs (via the CID circuit card), then to an interface test adapter, and then finally routed to the device(s) under test. This interface can be made to the device under tests card edge connector installed to a Printed Circuit Board (PCB), or via wiring.

Accordingly, a configurable interface test device in accordance with the present invention, and described herein, has many advantages such that it:
a. Allows many devices to be tested with a single ITA;
b. Reduces the size and weight of ITA's;
c. Improves signal integrity, through shorter signal paths and impedance matching;
d. Lowers cost through the reduction of design time labor, labor to build ITA's and the low cost of material contained in ITA's;
e. Reduces ITA design and assembly time;
f. Real Time Power-on safety feature to prevent damage to device under test;
g. Provides convenient test equipment signal routing to device pins; and
h. Connects directly to a wide variety of COTS test equipment.

It is important to note that the present invention is not intended to be limited to a device or method which must satisfy one or more of any stated or implied objects or features of the invention. It is also important to note that the present invention is not limited to the preferred, exemplary, or primary embodiment(s) described herein. Modifications and substitutions by one of ordinary skill in the art are considered to be within the scope of the present invention, which is not to be limited except by the following claims.

### BRIEF DESCRIPTION OF THE DRAWINGS

These and other features and advantages of the present invention will be better understood by reading the following detailed description, taken together with the drawings wherein:

FIG. 1 is a block diagram showing the configurable interface device (CID) of the present invention interfacing between electronic test equipment and a device under test;

FIG. 2 is a diagram showing a group of connectors making up an Equipment Interface Connector, in accordance with one feature of the present invention;

FIGS. 3A and 3B are diagrams illustrating various equipment adapters according to another feature of the present invention;

FIGS. 4A, 4B and 4C illustrate the signal routing for the CGAs and UGAs in accordance with another aspect of the present invention;

### DETAILED DESCRIPTION OF THE PREFERRED EMBODIMENTS

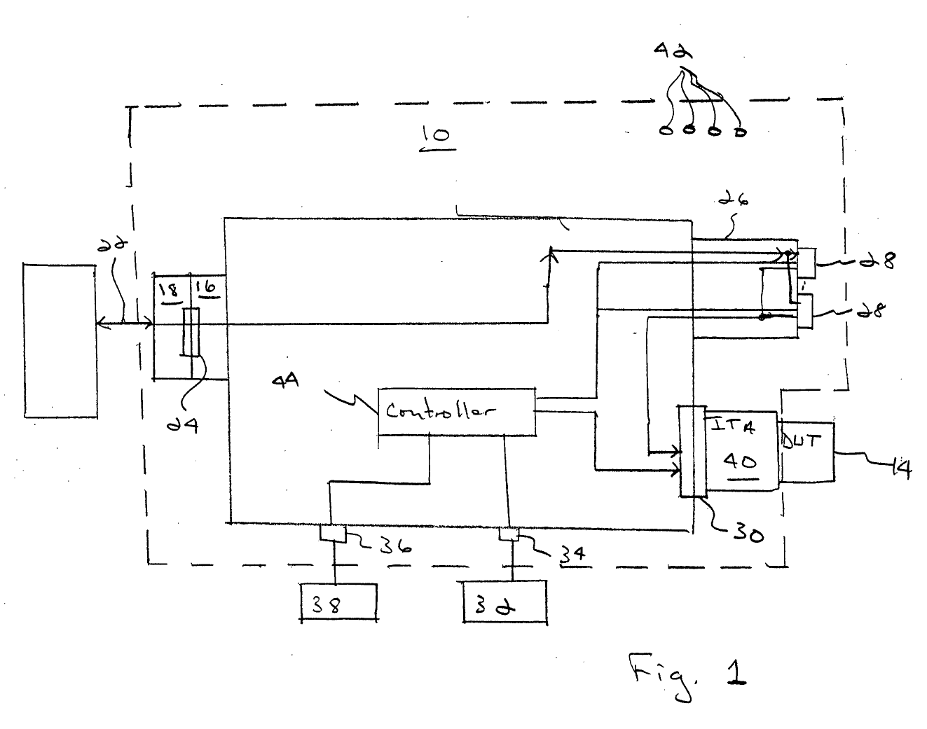

The present invention features a configurable interface device 10, FIG. 1, that serves as a mechanical and electrical interface between standard off-the-shelf or customized test equipment 12 and a device under test 14. A typical example of a device under test 14 is a printed circuit board assembly which is used, along with other circuit board assemblies, in a larger system.

The configurable interface device 10, of the present invention, includes an equipment interface connector (EIC) portion 16 and an equipment adapter (EA) portion 18.

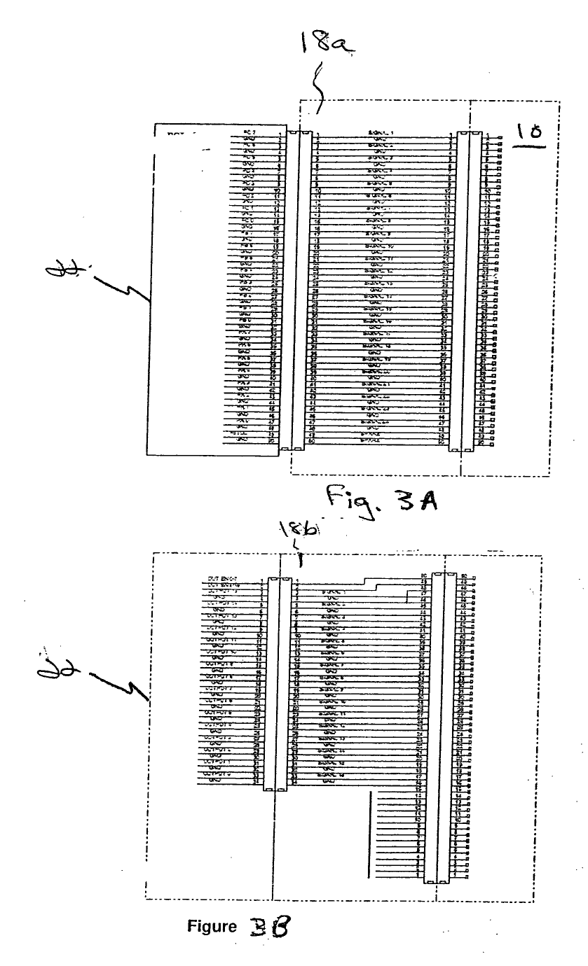

In order to interface standard test equipment 12 with the configurable interface device's Equipment Interface Connectors (EIC) 16, an equipment adapter 18 for each EIC is provided. The equipment adapter 18 may take the form of a ribbon cable 18a, FIG. 3A, or a circuit card 18b, FIG. 3B. One side of the equipment adapter 18 plugs into an EIC 16, while the other side accepts the test instrument's standard cable 22. A configurable interface device (CID) in accordance with the present invention will include one or more equipment adapter (EA) devices 18 as required by the user's specification. Equipment adapter devices 18 maintain constant signal length and impedance between the test instrument's standard cable(s) 22 and the configurable interface device equipment interface connector 10.

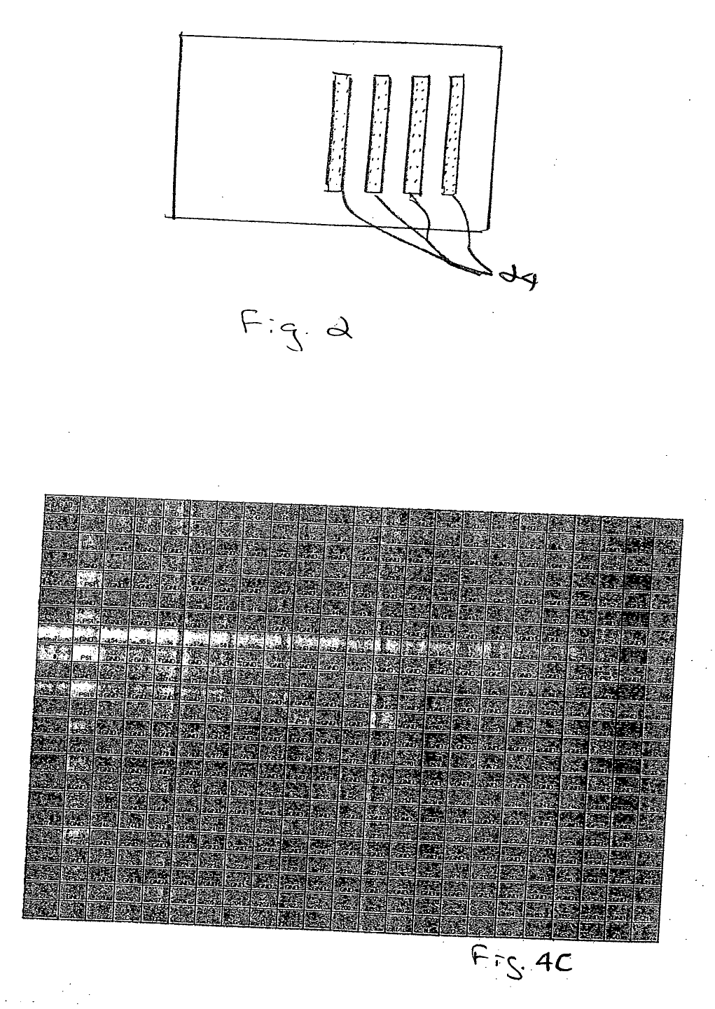

According to one embodiment of the present invention, each equipment interface connector (EIC) 16, FIG. 2, is a group comprised of, for example, four connectors 24, each of which is comprised of two rows of twenty-five pins with 0.1″ center-to-center spacing. There may be more than one group of EIC's 16. The equipment interface connector 24 accepts 0.1″ pitch fifty-pin ribbon cables with twenty-four alternate signal/ground pins and two spare signals. Although the present invention is explained in connection with a particular connector, this is not a limitation of the present invention as any type of connector in any of many sizes and configurations is within the scope of the present invention.

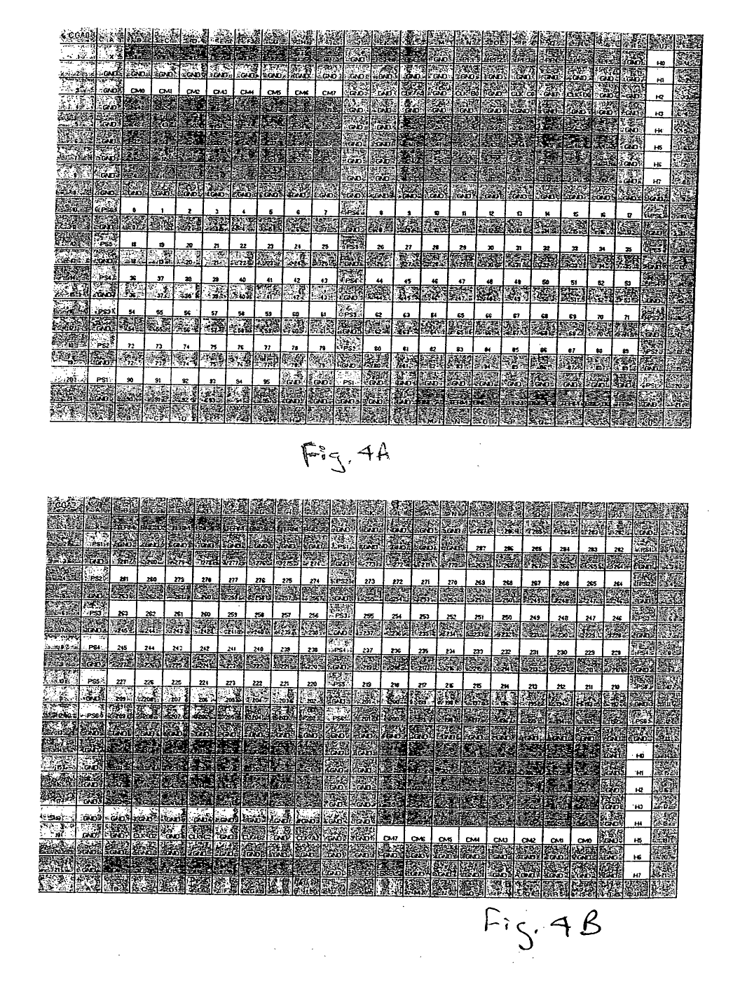

Each group of equipment interface connectors 24 is routed to each configurable grid array 28, 30, typically 96 Test Data signals TD0-TD95. All Test Data signals are designed for high signal integrity including, ground shielding for noise immunity, controlled impedance, and equal electrical length. The signals are further routed through the use of the wire wrap-able CGA Adapters 28. Signal routing on the CGA adapter 28 allows for short customizable signal runs that can be accomplished in a small, efficient, low cost package. This innovative universal signal routing at the CGA or UGA, eliminates redesign costs from various ITA when the device under test mating interface is the same. FIGS. 4A, 4B and 4C illustrate the signal routing for the CGAs and UGAs.

One or more bi-color (red/green) LEDs 42, FIG. 1, may be located on the top of the front panel as user-interface indicators. The LED state is controlled through external TTL input, the default color is red when power is applied.

One or more momentary switches may be located on the front panel. These firmware programmable switches provide user interface test controls. Multiple global clocks are also available at each CGA. Global clocks are input from an external device 32 to BNC connectors 34 located on the CID 10.

Four electrically phase matched clock signal traces are routed from the external BNC connectors to the equipment interface connectors 16. Phase matched clocks are input from an external device to clock custom circuit cards installed to an equipment interface connector. Eight global timing signals are also available at each CGA. Global timing signals are input from an external device to BNC connectors located at the bottom equipment side of the CID 10.

Eighty CGA pins are common signal traces between all CGAs (CGA0-CGA3). Seventy-two (72) of which are also connected to one equipment interface connector group. Twelve additional signal lines between EIC groups are unique to each of the four CGAs.

The CID 8-pin power interface connector 36 supports up to 6 power supplies 38. Each power supply 38 is routed into each of the four CGAs. Power supplies 1 and 2 are also routed to both UGAs. A power relay circuit, as is known to those skilled in the art, is mounted within the CID and controls each of the six individual power supplies. It controls the polarity, positive or negative, and the overall power enable for all power supplies simultaneously. The polarity signals are defined through electrical connections made on CGA0.

Input from the CID power control connector are defined as follows: power polarity is positive when no signal is connected to the associated power polarity pin on CGA0; when a power polarity pin is grounded at CGA0, the associated power supply will have a negative voltage; power is externally enabled when the Power Enable Signal is driven low by the onboard CID firmware. The Power enable control goes low when the following conditions have been met: (1) an external software ID check-word is sent externally via a standard serial interface; (2) a control pin is externally enabled; or (3), the ID check words exactly match the coded ID words for each CGA and UGA.

The software ID check-word and software enable are input to the CID from an external or internal controller 44 via 3 standard interface connectors. Each CGA/UGA has a unique 8-bit ID word. In addition, the CGAs have two additional ID pins. ID's are programmed on CGA/UGAs by wiring combinations of ID pins to ground. The ID check word and CGA/UGA ID words are input to a 56-bit magnitude comparator circuit contained on the CID. The user software must set the ID check word and instruct the operator to install the necessary CGA/UGA's then assert the software enable signal. Only when the ID check word matches the ID word will the power supplies be enabled.

An interface test adapter 40 provides a mechanical and electrical mating interfacing for a device under test 14. ITA signal routing is application specific depending on the ITA type. Three ITA types are typically used including: Platform Card Edge ITA's; Custom Card Edge ITA; and Custom Bed of Nails ITA's.

Platform interface test adapters refer to ITAs that are reusable for multiple devices which use the same input/output connector(s). Platform ITAs plug into UGA0 and/or UGA1. Custom Card Edge ITAs refer to an Adapter that is dedicated to testing one type of circuit card assembly (CCA). It contains custom circuitry dedicated to providing input/output test signal routing for that CCA. Custom bed of nails ITAs refer to an Adapter that is used for In-Circuit testing rather than Card Edge Testing. This Adapter type is connected directly to the four CGA's rather than via the UGAs. The test interface is through circuit probes directly contacting circuit nodes. Ken: I am not completely clear on what the differences are between a CGA and a UGA. Dan

As mentioned above, the present invention is not intended to be limited to a device or method which must satisfy one or more of any stated or implied objects or features of the invention and should not be limited to the preferred, exemplary, or primary embodiment(s) described herein. Modifications and substitutions by one of ordinary skill in the art are considered to be within the scope of the present invention, which is not to be limited except by the following claims.

The invention claimed is:

1. A configurable interface device, comprising:
a test equipment interface, for providing a mechanical and electrical connection to an electronic test equipment, for routing test signals to and from said electronic test equipment;
a user configurable signal connection array, electrically coupled to said test equipment interface and to a device under test adapter, for routing said test signals to and from a device under test; and
a device under test adapter, electrically coupled to said user configurable signal connection array, for providing a mechanical and electrical connection to said device under test, for routing test signals to and from said electronic test equipment and said device under test.

2. The configurable interface device of claim 1, wherein said test equipment interface further includes a test equipment interface adapter, for providing said mechanical and electrical connection between said test equipment interface and said electronic test equipment.

3. The configurable interface device of claim 2, wherein said test equipment interface adapter includes a ribbon cable.

4. The configurable interface device of claim 2, wherein said test equipment interface adapter includes a circuit card.

5. The configurable interface device of claim one, further including a configurable interface device controller, responsive to input signals from said user configurable signal connection array, for controlling application of power to said device under test.

6. A configurable interface device, comprising:
a test equipment interface, for providing a mechanical and electrical connection to an electronic test equipment, for routing test signals to and from said electronic test equipment, said test equipment interface further including a test equipment interface adapter, for providing said mechanical and electrical connection between said test equipment interface and said electronic test equipment;
a user configurable signal connection array, electrically coupled to said test equipment interface and to a device under test adapter, for routing said test signals to and from a device under test; and
a device under test adapter, electrically coupled to said user configurable signal connection array, for providing a mechanical and electrical connection to said device under test, for routing test signals to and from said electronic test equipment and said device under test.
